(19) United States
(12) Patent Application Publication
(10) Pub. No.: US 2024/0213058 A1
(43) Pub. Date: Jun. 27, 2024

(54) LOAD LOCK ARRANGEMENTS, ASSOCIATED TEMPERATURE CONTROL ASSEMBLIES, AND SEMICONDUCTOR PROCESSING SYSTEMS INCLUDING LOAD LOCK ARRANGEMENTS AND TEMPERATURE CONTROL ASSEMBLIES

(71) Applicant: ASM IP Holding B.V., Almere (NL)

(72) Inventors: Masaei Suwada, Nagaoka-shi (JP); Taira Okabe, Kawasaki-shi (JP)

(21) Appl. No.: 18/392,301

(22) Filed: Dec. 21, 2023

Related U.S. Application Data
(60) Provisional application No. 63/476,985, filed on Dec. 23, 2022.

(51) Int. Cl. H01L 21/67

(52) U.S. Cl. CPC H01L 21/67201; H01L 21/67248

(57) ABSTRACT

Load lock assemblies and associated temperature control assemblies are disclosed. The temperature control assemblies are moveably disposed within a load lock chamber body and constructed and arranged to be inserted and extracted from the load lock chamber body.

### CROSS-REFERENCE TO RELATED APPLICATION(S)

This Application claims the benefit of U.S. Provisional Application 63/476,985 filed on Dec. 23, 2022, the entire contents of which are incorporated herein by reference.

### FIELD OF INVENTION

The present disclosure relates generally to the field of semiconductor processing methods and systems, and to the field of device and integrated circuit manufacture. More particularly, the present disclosure relates to load lock arrangements, and associated temperature control assemblies moveably disposed within the load lock arrangements.

### BACKGROUND OF THE DISCLOSURE

Semiconductor processing systems, such as semiconductor processing systems with cluster-type platforms, commonly include a front-end connected to a back-end by a load lock. The front-end generally interfaces the semiconductor processing system to the external environment and typically includes a front-end robot to transfer substrates between the front-end of the semiconductor processing system and the load lock. The back-end typically includes a process module wherein substrate processing is accomplished and a wafer transfer chamber including a back-end robot to transfer substrates between the load lock and the process module. The load lock generally couples the back-end of the semiconductor processing system to the front-end of the semiconductor processing system and is typically arranged to isolate the environment maintained in the back-end of the semiconductor processing system to the environment maintained in the front-end of the semiconductor processing system.

The coupling of load locks to various semiconductor processing apparatus and systems can result in limited space for system fabrication and maintenance which can result in difficulties in the removal and insertion of various assemblies employed within the load locks and associated semiconductor processing systems. Accordingly, improved load lock arrangements and associated moveable temperature control assemblies are desirable.

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior ar.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In particular, the present disclosure describes load lock arrangements including, a load lock chamber body comprising, a first face constructed and arranged for coupling with a transfer module, a second face constructured and arranged for coupling with a vacuum chamber, and at least one sidewall including one or more sidewall apertures. In addition, the load lock arrangements of the present disclosure can include, a temperature control assembly moveably disposed within the load lock chamber body and constructured and arranged to be inserted and extracted through the one or more sidewall apertures. In addition, the load lock arrangements of the present disclosure can include, a temperature control assembly comprising, a head portion including both a heating mechanism and a cooling mechanism, a neck portion connected to the head portion, and a sealing flange connected to the neck portion, wherein the sealing flange is configured for forming a seal over the one or more sidewall apertures.

In some embodiment, the head portion comprises, a thermal plate including an upper surface and a lower surface, wherein the upper surface is constructed and arranged to convey heating and/or cooling to a substrate disposed over the thermal plate.

In some embodiment, the cooling mechanism is disposed within the head portion and comprises one or more sealed channels disposed within the head portion through which a cooling fluid is introduced and withdrawn.

In some embodiment, the one or more sealed channels extend into and are disposed within the neck portion, and the sealing flange of the temperature control assembly, thereby forming one or more fluidic conduits between the head portion, the neck portion, and the sealing flange.

In some embodiment, the heating mechanism comprises, one or more heating elements disposed within or on the head portion of the temperature control assembly.

In some embodiment, the one or more heating elements comprise, resistive heating elements which are electrically connected via conductive lines which extend into the neck portion, and the sealing flange of the temperature control assembly, thereby forming an electrical connection between the one or more heating elements portion, through the neck portion, and through the sealing flange.

In some embodiment, the head portion has a width that is wider than the neck portion.

In some embodiment, the head portion has a maximum thickness between 6 and 18 millimeters.

In some embodiment, the load lock arrangements of present disclosure further comprises, an upper load lock chamber (ULLC) and a lower load lock chamber (LLLC), an upper sidewall aperture and a lower sidewall aperture, an upper temperature control assembly moveably disposed within the upper load lock chamber and constructured and arranged to be inserted and extracted through the upper sidewall aperture, and a lower temperature control assembly moveably disposed within the lower load lock chamber and constructured and arranged to be inserted and extracted through the lower sidewall aperture.

In some embodiment, the upper temperature control assembly comprises, an upper sealing flange which is constructured and configured to form a vacuum seal over the upper sidewall aperture and the lower temperature control assembly comprises, a lower sealing flange which is constructed and configured to form a vacuum seal over the lower sidewall aperture.

In some embodiment, the upper load lock chamber (ULLC) and the lower load lock chamber (LLLC) can each accommodate 2 (two) temperature control assemblies disposed therein concurrently, and thereby the load lock chamber body can accommodate 4 (four) temperature control assemblies concurrently, each of the 4 (four) temperature control assemblies including both heating and cooling mechanisms.

The present disclosure also describes semiconductor processing systems comprising, a process module, a wafer handling chamber connected to the process module and housing a back-end substrate transfer robot, a load lock arrangement as disclosure herein connected to the wafer handling chamber and coupling the process module to an equipment front-end module housing a front-end substrate transfer robot, wherein the front-end substrate transfer robot and the back-end substrate transfer robot are configured to transfer substrates between the equipment front-end module and the process module through the upper load lock chamber and the lower load lock chamber.

In some embodiment, one or more temperature control assemblies are inserted and extracted from the load lock arrangement with sufficient clearance to prevent contact with the process module.

In some embodiment, the process module comprises a Quad Chamber Module (QCM).

The present disclosure also describes temperature control assemblies comprising, a head portion including both a heating mechanism and a cooling mechanism, a neck portion connected to the head portion, and a sealing flange connected to the neck portion, wherein the sealing flange is configured for forming a seal over one or more sidewall apertures of a load lock chamber body.

In some embodiment, the head portion has a width that is wider than the neck portion.

In some embodiment, the head portion has a maximum thickness between 6 and 18 millimeters.

In some embodiment, the head portion comprises a thermal plate including, an upper surface and a lower surface, wherein the upper surface is constructed and arranged to convey heating and/or cooling to a substrate disposed over the thermal plate.

In some embodiment, the cooling mechanism is disposed within the head portion and comprises one or more sealed channels disposed within the head portion through which a cooling fluid is introduced and withdrawn, and wherein the one or more sealed channels extend into and are disposed within the neck portion, and the sealing flange of the temperature control assembly, thereby forming one or more fluidic conduits between the head portion, the neck portion, and the sealing flange.

In some embodiment, the heating mechanism comprises, one or more heating elements disposed within or on the head portion of the temperature control assembly, and wherein the one or more heating elements comprise resistive heating elements which are electrically connected via conductive lines which extend from the one or more heating elements, into and through the neck portion, and into and through the sealing flange.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a plan view of a semiconductor processing system in accordance with at least one embodiment of the present disclosure;

FIG. 2 illustrates a view of the internal configuration a semiconductor processing system in accordance with at least one embodiment of the present disclosure;

FIG. 3 illustrates a simplified view of a load lock arrangement in accordance with at least one embodiment of the present disclosure

FIG. 4 illustrates a three dimensional view of an exemplary temperature control assembly in accordance with at least one embodiment of the present disclosure;

FIG. 5 illustrates a plan view of an exemplary temperature control assembly in accordance with at least one embodiment of the present disclosure; and

FIG. 6 illustrates a cross-sectional view of an exemplary temperature control assembly in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

In this disclosure, any defined meanings do not necessarily exclude ordinary and customary meanings in some embodiments.

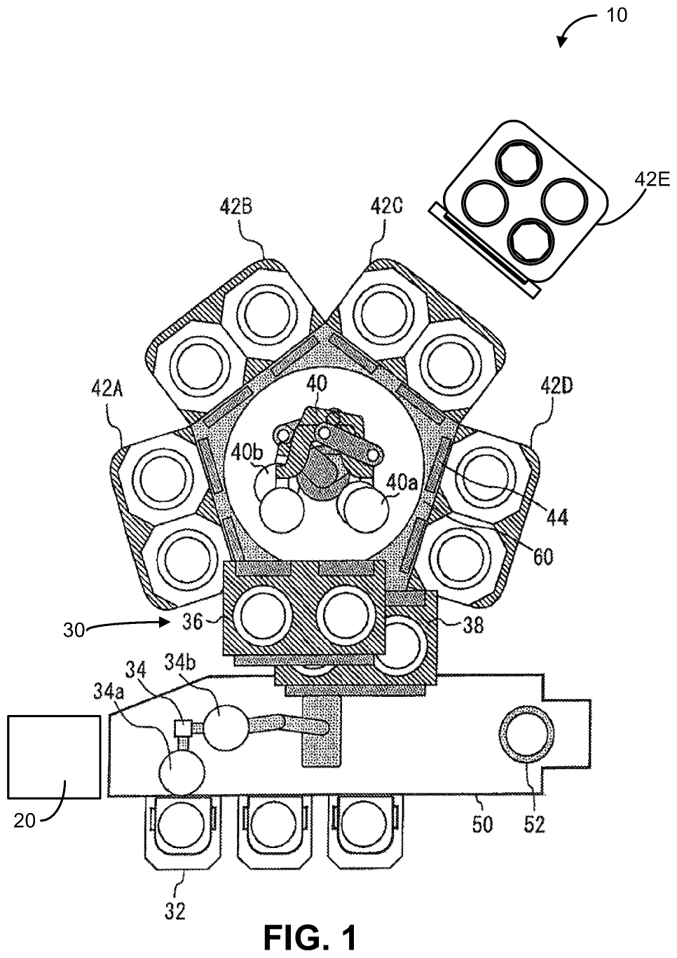

FIG. 1 is a plan view of an exemplary the semiconductor processing system 10 in accordance with the embodiments of the present disclosure. The semiconductor processing system 10 can include, at least one load port 32, a front-end substrate transfer robot 34, and a load lock arrangement 30, including an upper load lock chamber (ULLC) 36, a lower load lock chamber (LLLC) 38, a back-end substrate transfer robot 40, a first process module 42A, a second process module 42B, a third process module 42C, a fourth process module 42D, and gate valves 44. These components are connected to and controlled by a controller 20.

In some embodiments of the disclosure, the exemplary semiconductor processing system 10 can include an equipment front-end module (EFEM) 50. A front-end substrate transfer robot 34 and a plurality of cooling stages 50 and 52 can be provided in the EFEM 50. The front-end substrate transfer robot 34 can be provided with an upper arm 34a and a lower arm 34b and hence is capable of transferring two substrates separately. A substrate can be mounted on each cooling stage 52 and cooled. The load port 32, the ULLC 36, and the LLLC 38 are connected to the EFEM 50. The ULLC 36 is located directly above the LLLC 38. Although the ULLC 36 is shown in FIG. 1 to be displaced relative to the LLLC 38 and cover only the upper left portion of the LLLC 38, for convenience of illustration. The front-end substrate transfer robot 34 is used to transfer a substrate(s) between any two of the load port 32, the ULLC 36, the LLLC 38, and the cooling stages 52.

The exemplary semiconductor processing system 10 further includes a vacuum chamber 60, which is also referred to herein as a wafer handling chamber. A back-end substrate transfer robot 40 is provided in the vacuum chamber 60. The back-end substrate transfer robot 40 is provided with two upper arms 40a and two lower arms 40b and hence is capable of transferring two pairs of substrates separately.

In some embodiments, the ULLC 36, the LLLC 38, and the first to fourth process modules 42A, 42B, 42C, and 42D are connected to the vacuum chamber 60. The first process module 42A can be configured as a dual chamber module (DCM) to process two substrates concurrently. The second to fourth process modules 42B, 42C, and 42D can also configured as a dual chamber modules to also process two substrates concurrently. In some embodiments, the process module 42A, 42B, 42C, and 42D, may be configured as a Quad Chamber Module (QCM) to process four substrates concurrently. An exemplary, Quad Chamber Module (QCM) 42E that could be employed on the semiconductor processing systems of the present disclosure is illustrated in FIG. 1.

The back-end substrate transfer robot 40 can be used to transfer substrate(s) between the ULLC 36 or the LLLC 38 and any one of the process modules 42A, 42B, 42C, and 42D. Gate valves 44 are provided between the vacuum chamber 60 (i.e., the wafer handling chamber) and the process modules 42A, 42B, 42C, and 42D, additional gate valves can be provided between the vacuum chamber 60 and the ULLC 36 and the LLLC 38, and further gate valves can be provided between the EFEM 50 and the ULLC 50 and the ULLC 38.

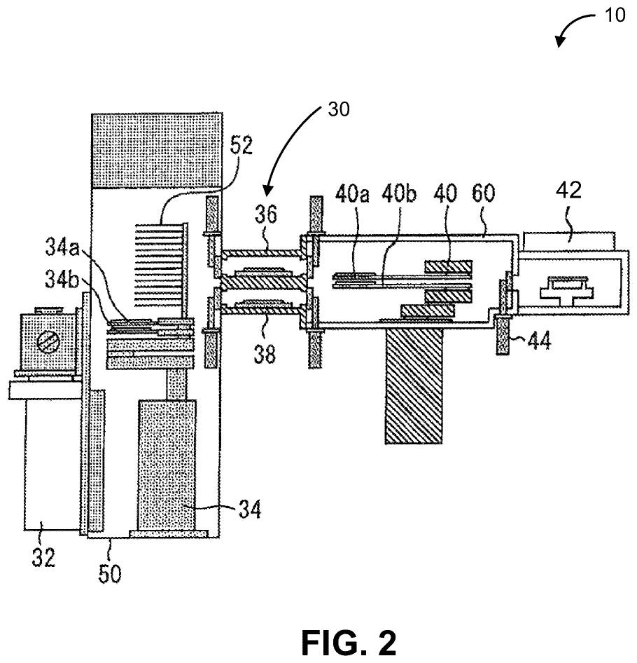

FIG. 2 illustrates an exemplary view of the internal configuration of the semiconductor processing system 10 in accordance the embodiment of the present disclosure. In this example, there are 14 cooling stages 52 so that 14 substrates can be held and air-cooled concurrently.

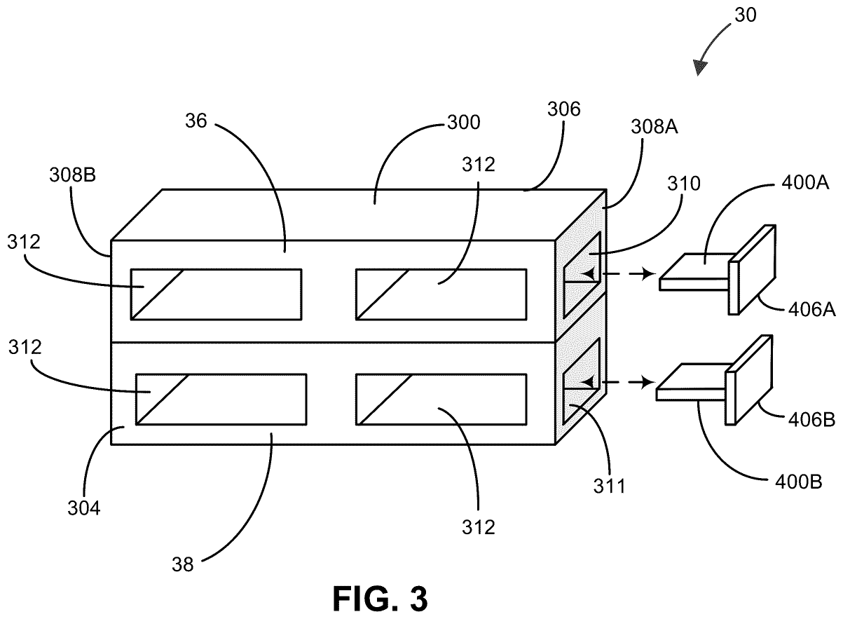

FIG. 3 illustrates a simplified view of a load lock arrangement 30 according to the embodiments of the present disclosure. The load lock arrangement 30 can include, a load lock chamber body 300 and one or more moveable temperature control assemblies 400A and 400B. The load lock chamber body 300 can include a first face 304 constructed and arranged for coupling with a transfer module (such as EFEM 50 of FIG. 1) and a second face 306 constructured and arranged for coupling with a vacuum chamber (such as vacuum chamber 60 of FIG. 1). The load lock chamber body 300 can also include one or more sidewalls 308A and 308B including one or more sidewall apertures 310 and 311. The load lock chamber body 300 can further include multiple apertures 312 for the transfer of substrates into and out of the load lock chamber arrangement 30.

The load lock chamber arrangement 30 (FIG. 3) can also include one or more temperature control assemblies 400A and 400B (here shown in a simplified form) which can be moveably disposed within the load lock chamber body 300 and are constructed and arranged to be inserted and extracted through the one or more sidewall apertures 310 and 311 disposed within the load lock chamber body 300. As illustrated in FIG. 3, the simplified temperature control assemblies 400A and 400B are shown withdrawn from the load lock chamber body 300 with the exemplary dashed arrows demonstrating the movement of the temperature control assemblies 400A and 400B for insertion and extraction of the temperature control assemblies 400A and 400B though the one or sidewall apertures 310 and 311, wherein the temperature control assemblies 400A and 400B include sealing flanges 406A and 406B which enable a vacuum seal to be form upon insertion in the load lock chamber body 300. It should be noted that the movement direction arrows illustrated in FIG. 3 are an exemplary demonstration of the insertion and extraction path of the temperature control assemblies 400A and 400B and additional pathways for insertion and extraction can be employed. In some embodiment, the temperature control assemblies 400A and 400B may be identical.

In additional embodiments of the disclosure and with further reference to FIG. 3, the load lock arrangement 30 can further comprise, an upper load lock chamber (such as upper load lock chamber 36) and a lower load lock chamber (such as lower load lock chamber 38). The load lock chamber arrangement 30 can further include, an upper sidewall aperture 310 and a lower sidewall aperture 311. The load lock chamber arrangement 30 can also comprise, an upper temperature control assembly 400A moveably disposed within the upper load lock chamber 36 and constructed and arranged to be inserted and extracted through the upper sidewall aperture 310, and a lower temperature control assembly 400B moveably disposed within the lower load lock chamber 38 and constructed and arranged to be inserted and extracted through the lower sidewall aperture 311. In additional embodiments, the upper temperature control assembly 400A comprises an upper sealing flange 406A which is constructured and configured to form a vacuum seal over the upper sidewall aperture 310 and the lower temperature control assembly 400B comprises a lower sealing flange 406B which is constructed and configured to form a vacuum seal over the lower sidewall aperture 311. It should be noted that FIG. 3 illustrates an example where two temperature control assemblies 400A and 400B can be moveably disposed within the load lock chamber body 30 through upper and lower sidewall apertures 310 and 311, however it should be appreciated that the opposing sidewall 308B of load lock chamber 300 can also include upper and lower apertures into which two (2) further temperature control assemblies can inserted and extracted (not shown).

Therefore, in some embodiments, the upper load lock chamber (ULLC) 36 and the lower load lock chamber (LLLC) 38 can each accommodate 2 (two) temperature control assemblies disposed therein concurrently, and thereby the load lock chamber body 300 can accommodate 4 (four) temperature control assemblies concurrently, each of the 4 (four) temperature control assemblies including both heating and cooling mechanisms.

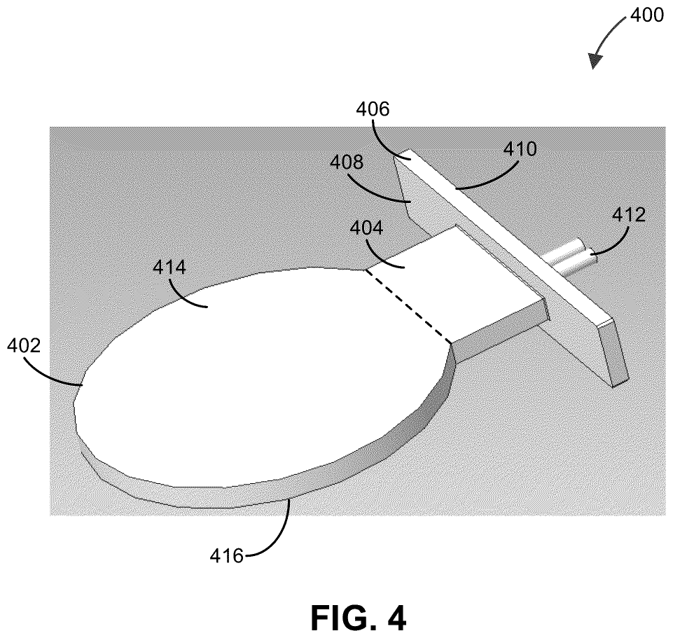

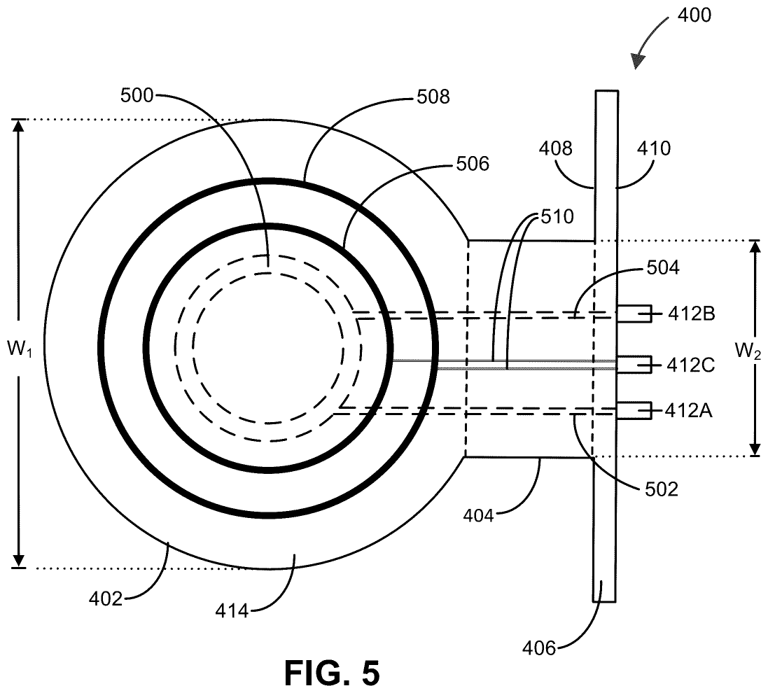

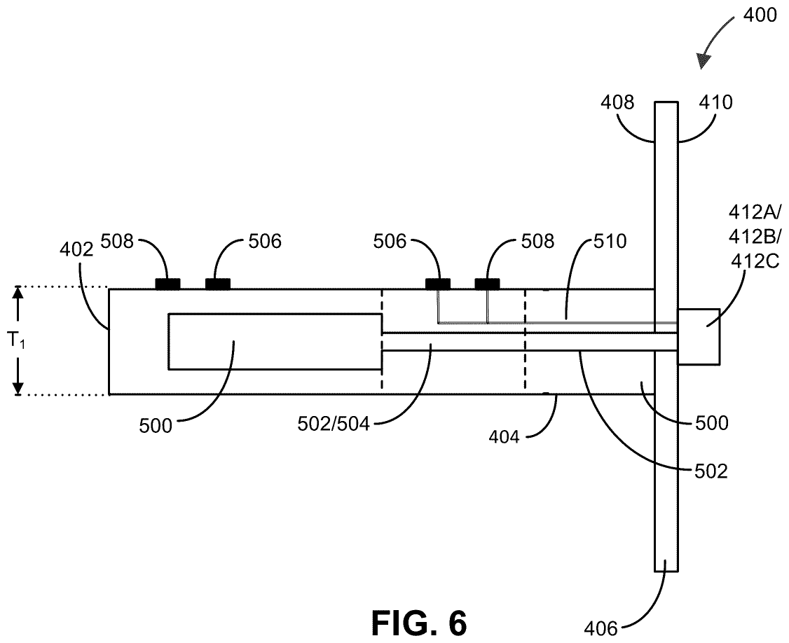

The temperature control assemblies 400 of the present disclosure are shown in greater detail in FIG. 4, FIG. 5, and FIG. 6. For example, FIG. 4 illustrates a three dimensional view of an exemplary temperature control assembly 400 in accordance the embodiments of the present disclosure. In some embodiments, the exemplary temperature control assembly 400 comprises, a head potion 402 including both a heating and cooling mechanism (not shown in FIG. 4 but illustrated and described in greater herein below with reference to FIG. 5 and FIG. 6). The exemplary temperature control assembly 400 can further comprises, a neck portion 404 connected to the head portion 402, and a sealing flange 406 connected to the neck portion 404, wherein the sealing flange is configured for forming a seal over the one or more sidewall apertures (such as sidewall apertures 310 and 311 of FIG. 3).

For example, the sealing flange 406 can comprise a vacuum sealing surface 408 which can be configured to form a vacuum sealing surface with a sidewall of the load lock chamber body thereby sealing the sidewall apertures (e.g., 310 and 311 of FIG. 3) into which the temperature control assembly are inserted. In some embodiments, the vacuum sealing surface 408 may include further elements to aid in providing a vacuum seal between the vacuum sealing surface 408 and a sidewall of the load lock chamber body, such as, vacuum O-rings and gaskets, for example.

In addition, the sealing flange 406, and particularly the vacuum sealing surface 408, is dimensioned to be greater in length and height than the sidewall apertures of the load lock chamber body to ensure a vacuum seal is created between the vacuum sealing surface 408 and the sidewalls of the load lock chamber body. The sealing flange 406 also comprises, an outer sealing flange surface 410 which can further include one or more ports 412 disposed therein which can be configured to allow the heating and cooling mechanism to be provided to the head portion 402 of the temperature control assembly (described in greater detail herein below). The exemplary temperature control assembly 400 as illustrated in FIG. 4 includes two (2) ports, however additional ports (or less ports) may be utilized depending on the mechanisms utilized for heating and cooling the assembly 400.

In some embodiments, the head portion 402, the neck portion 404, and the sealing flange 406, and the one or more ports 412 may comprise separate elements that can connected during fabrication of the temperature control assembly 400 or alternatively the temperature control assembly 400 may be constructure from a single element, or one or more elements.

In some embodiments, the head portion 402 of the exemplary temperature control assembly 400 can comprise a thermal plate including an upper surface 414 and a lower surface 416, wherein the upper surface 414 can be constructed and arranged to convey heating and/or cooling to a substrate disposed over the thermal plate. Alternative, the thermal plate can provide heating and/or cooling to the internal volume of the upper load lock chamber and/or the lower lock chamber.

In some embodiment, the head portion of the temperature control assembly can include both heating and cooling mechanisms. For example, FIG. 5 illustrates a plan view of an exemplary temperature control assembly 400 and FIG. 6 illustrates a cross-sectional view of an exemplary temperature control assembly 400, wherein FIG. 5 and FIG. 6 illustrate exemplary cooling mechanisms and heating mechanisms employed within the temperature control assemblies of the present disclosure.

For example, in some embodiments, a cooling mechanism is disposed within the head portion of the temperature control assembly, i.e., the thermal plate. As a non-limiting example, the cooling mechanism disposed within the head portion of the temperature control assembly can comprise one or more sealed channels disposed within the head portion, i.e., the thermal plate, through which a cooling fluid can be introduced and withdrawn.

FIG. 5 and FIG. 6 illustrate an exemplary cooling mechanism comprising a cooling channel 500 fed by a cooling inlet 502 (via port 412A) and cooling outlet 504 (via port 412B). In some embodiments, the one or more sealed channels extend and are disposed within the neck portion 404, and the sealing flange 406 of the temperature control assembly 400, thereby forming one or more fluidic conduits between the head portion 402, the neck portion 404, and the sealing flange 406. As illustrated in the plan view illustration of FIG. 5 the cooling channel 500, and the cooling channel inlet 502 and outlet ports 504 are denoted by dashed line to signify they are disposed within the temperature control mechanism 400.

As a non-limiting example, the cooling channel 500, can be supplied with a cooling fluid through the cooling inlet 502 which is fluid communication with port 412A, and the cooling fluid can be extracted from the cooling channel 500 through the cooling outlet 504 which is fluid communication with port 412B. In some embodiments, the ports 412A and the 412B can be fluidly connected to a chiller system which provides a temperature controlled fluid to the thermal plate (i.e., head portion 402). For example, the chiller system can supply temperature controlled water, or Galden® PFPE, to the cooling channel 500.

In some embodiments, alternative cooling mechanisms and configurations can be utilized. As non-limiting examples, sealed cooling channels can be disposed on or embedded within the upper surface 414 of the head portion 402 of the temperature control assembly 400, or a thermoelectric cooling mechanism (e.g., a Peltier cooling mechanism) can be disposed in or on head portion 402

In some embodiments, a heating mechanism can also be provided to the temperature control mechanism. For example, the heating mechanism can comprise, one or more heating elements disposed within or on the head portion of the temperature control assembly. In some embodiments, the one or more heating elements (such as elements 506 and 508) can comprise resistive heating elements which are electrically connected via conductive lines 510 which extend into the neck portion 404, and the sealing flange 406 of the temperature control assembly 400, thereby forming an electrical connection to the one or more heating elements disposed on or in the head portion 402 (the thermal plate), to the neck portion, and the sealing flange 406.

As a non-limiting example, the exemplary heating elements 506 and 508, can be electrically connected via port 412C. It should be noted that the dimensions and layout of the heating elements shown in FIG. 5 and FIG. 6 are exemplary and it is noted that the heating element(s) can have different geometries and dimensions, as well as including multiple independently controlled heating zones comprising multiple independently controlled heating elements. For example, the conductive lines 510 can be connected to a controller that enables multizone heating to the thermal plate (i.e., head portion 402).

In some embodiments, alternative heating mechanisms and configurations can be utilized. As a non-limiting example, inductive heating elements may be employed within or on head portion 402.

Therefore, the load lock arrangements of the present disclosure allow for the insertion and extraction of multiple temperature control assemblies into and out of the load lock chamber body through one or more sidewall apertures which thereby enables ease of access for fabrication and maintenance of the load lock arrangements and associated semiconductor processing systems of the present disclosure. To further enable ease of access and maintenance of the load lock assemblies and associated semiconductor processing systems of the present disclosure, the temperature controlled assemblies moveably disposed within the load lock chamber body are dimensioned to increase ease of insertion and extraction.

Therefore, in some embodiments, the head portion of the one or more temperature control assemblies has a width that is wider than the neck portion. For example, referring again to FIG. 5, the head portion 402 of the temperature control assembly has a width (W₁) that is wider than the width of the neck portion 404 (W₂).

In addition to sizing the head portion and the neck portion of the temperature control assemblies to enable ease of insertion and extraction, the thickness of the temperature control assemblies can be minimized. For example and with reference to FIG. 6, in some embodiments, the head portion 402 can have a maximum thickness (T₁) less than 25 millimeters, or less than 20 millimeters, or less than 15 millimeters, or less than 10 millimeters, or less than 5 millimeters, or between 5 and 25 millimeters, or between 5 and 20 millimeters, or between 6 and 18 millimeters.

Therefore, semiconductor processing systems including the load lock arrangements of the present disclosure provide improved system fabrication and maintenance due to ease of insertion and extraction of the temperature control assemblies employed in the load lock arrangements of the present disclosure for providing heating and cooling to substrates loaded therein.

For example and with reference to FIG. 2 and FIG. 3, the embodiments of the present disclosure may further include a semiconductor processing system 10 comprising, a process module 42, a wafer handling chamber 60 connected to the process module 42 and housing a back-end substrate transfer robot 40, a load lock arrangement 30 as disclosure in the present disclosure (such as load lock arrangement 30 of FIG. 3) connected to the wafer handling chamber 60 and coupling the process module 42 to an equipment front-end module 50 housing a front-end substrate transfer robot 34, wherein the front-end substrate transfer robot 34 and the back-end substrate transfer robot 40 are configured to transfer substrates between the equipment front-end module 50 and the process module 42 through the upper load lock chamber 36 (FIG. 3) and the lower load lock chamber 38 (FIG. 3).

The semiconductor processing system of the current disclosure may further comprise, one or more temperature control assemblies (such as temperature control assemblies 400A and 400B of FIG. 3) that can be inserted and extracted from the load lock arrangement 30 with sufficient clearance to prevent contact either with the process module 42 and/or the wafer handling chamber 60, depending on the configuration of the semiconductor processing system.

For example, in some embodiments, a semiconductor processing system of the present disclosure may include one or more process modules 42 configured as a Quad Chamber Modules (QCM) to process four substrates concurrently. In such embodiments, the one or more temperature control assemblies (such as temperature control assemblies 400A and 400B of FIG. 3) can be inserted and extracted from the load lock arrangement 30 with sufficient clearance to prevent contact with the one or more Quad Chamber Modules (QCM).

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A load lock arrangement, comprising:
a load lock chamber body comprising,
a first face constructed and arranged for coupling with a transfer module, a second face constructured and arranged for coupling with a vacuum chamber, and at least one sidewall including one or more sidewall apertures;
a temperature control assembly moveably disposed within the load lock chamber body and constructured and arranged to be inserted and extracted through the one or more sidewall apertures, the temperature control assembly comprising;
a head portion including both a heating mechanism and a cooling mechanism;
a neck portion connected to the head portion; and
a sealing flange connected to the neck portion, wherein the sealing flange is configured for forming a seal over the one or more sidewall apertures.

2. The load lock arrangement of claim 1, wherein the head portion comprising a thermal plate which includes, an upper surface and a lower surface, wherein the upper surface is constructed and arranged to convey heating and/or cooling to a substrate disposed over the thermal plate.

3. The load lock arrangement of claim 1, wherein the cooling mechanism is disposed within the head portion and comprises, one or more sealed channels disposed within the head portion through which a cooling fluid is introduced and withdrawn.

4. The load lock arrangement of claim 3, wherein the one or more sealed channels extend into and are disposed within the neck portion, and the sealing flange of the temperature control assembly, thereby forming one or more fluidic conduits between the head portion, the neck portion, and the sealing flange.

5. The load lock arrangement of claim 1, wherein the heating mechanism comprises, one or more heating elements disposed within or on the head portion of the temperature control assembly.

6. The load lock arrangement of claim 5, wherein the one or more heating elements comprise resistive heating elements which are electrically connected via conductive lines which extend into the neck portion, and the sealing flange of the temperature control assembly, thereby forming an electrical connection between the one or more heating elements, through the neck portion, and through the sealing flange.

7. The load lock arrangement of claim 1, wherein the head portion has a width that is wider than the neck portion.

8. The load lock arrangement of claim 1, wherein the head portion has a maximum thickness between 6 and 18 millimeters.

9. The load lock arrangement of claim 1, further comprises:
an upper load lock chamber (ULLC) and a lower load lock chamber (LLLC);
an upper sidewall aperture and a lower sidewall aperture;
an upper temperature control assembly moveably disposed within the upper load lock chamber and constructured and arranged to be inserted and extracted through the upper sidewall aperture; and
a lower temperature control assembly moveably disposed within the lower load lock chamber and constructured and arranged to be inserted and extracted through the lower sidewall aperture.

10. The load lock arrangement of claim 9, wherein the upper temperature control assembly comprises an upper sealing flange which is configured to form a vacuum seal over the upper sidewall aperture and the lower temperature control assembly comprises a lower sealing flange which is constructed and configured to form a vacuum seal over the lower sidewall aperture.

11. The load lock arrangement of claim 9, wherein the upper load lock chamber (ULLC) and the lower load lock chamber (LLLC) are each configured to accommodate 2 (two) temperature control assemblies disposed therein concurrently, and thereby the load lock chamber body is configured to accommodate 4 (four) temperature control assemblies concurrently, each of the 4 (four) temperature control assemblies including both heating and cooling mechanisms.

12. A semiconductor processing system, comprising:
a process module;
a wafer handling chamber connected to the process module and housing a back-end substrate transfer robot; and
a load lock arrangement as recited in claim 9 connected to the wafer handling chamber and coupling the process module to an equipment front-end module housing a front-end substrate transfer robot,
wherein the front-end substrate transfer robot and the back-end substrate transfer robot are configured to transfer substrates between the equipment front-end module and the process module through the upper load lock chamber and the lower load lock chamber.

13. The semiconductor processing system of claim 12, wherein one or more temperature control assemblies are configured to be inserted and extracted from the load lock arrangement with sufficient clearance to prevent contact with the process module.

14. The semiconductor processing system of claim 12, wherein the process module comprises a Quad Chamber Module (QCM).

15. A temperature control assembly, comprising:
a head portion including both a heating mechanism and a cooling mechanism;
a neck portion connected to the head portion; and
a sealing flange connected to the neck portion, wherein the sealing flange is configured for forming a seal over one or more sidewall apertures of a load lock chamber body.

16. The temperature control assembly of claim 15, wherein the head portion has a width that is wider than the neck portion.

17. The temperature control assembly of claim 15, wherein the head portion has a maximum thickness between 6 and 18 millimeters.

18. The temperature control assembly of claim 15, wherein the head portion comprising a thermal plate including, an upper surface and a lower surface, wherein the upper surface is constructed and arranged to convey heating and/or cooling to a substrate disposed over the thermal plate.

19. The temperature control assembly of claim 15, wherein the cooling mechanism is disposed within the head portion and comprises, one or more sealed channels disposed within the head portion through which a cooling fluid is introduced and withdrawn, and wherein the one or more sealed channels extend into and are disposed within the neck portion, and the sealing flange of the temperature control assembly, thereby forming one or more fluidic conduits between the head portion, the neck portion, and the sealing flange.

20. The temperature control assembly of claim 14, wherein the heating mechanism comprises, one or more heating elements disposed within or on the head portion of the temperature control assembly, and wherein the one or more heating elements comprise, resistive heating elements which are electrically connected via conductive lines which extend from the one or more heating elements, into and through the neck portion, and into and through the sealing flange.
